(19) United States
(12) Patent Application Publication
(10) Pub. No.: US 2003/0129272 A1
(43) Pub. Date: Jul. 10, 2003

(54) Mold for an integrated circuit package

(76) Inventors: Chi-Chih Shen, Kao-Hsiung Shih (TW); Shin-Shyan Hsieh, Kao-Hsiung Shih (TW)

Correspondence Address: J.C. Patents, Inc., 4 Venture, Suite 250, Irvine, CA, 92618, US

(21) Appl. No.: 10/139,690

(22) Filed: May 2, 2002

(30) Foreign Application Priority Data
Jan. 7, 2002 (TW) 91100095

(51) Int. Cl. B29C 45/14; B29C 70/72; H01L 21/56

(52) U.S. Cl. 425/123; 425/127

(57) ABSTRACT

A mold for an integrated circuit package. The mold for an integrated circuit package includes a main cavity, a front cavity, a rear cavity, a plurality of gates and a plurality of air vents. The gates and the air vents are located on two opposite sides of the mold respectively. The front cavity is located between the main cavity and the gates and the rear cavity is located between the main cavity and the air vents. The gates, the front cavity, the main cavity, the rear cavity and the air vents are interconnected so that they share a common inner space. The extension direction of the rear cavity is parallel to the arrangement direction of the air vents, and the extension direction of the front cavity is parallel to the arrangement direction of the gates. The width of the rear cavity is much smaller than the width of the main cavity.

### CROSS-REFERENCE TO RELATED APPLICATION

This application claims the priority benefit of Taiwan application serial no. 91100095, filed Jan. 7, 2002.

### SCENARIO OF THE INVENTION

1. Field of the Invention

The present invention relates in general to a mold with a baffles block. More particularly, the invention relates to a mold with a baffle block near the vent.

2. Description of the Related Art

In accordance with the continuous progression of electric technology, advertisements ceaselessly promote products with more humanized characteristics that provide more complex functions. The design trend always tends to lighter, thinner, shorter and smaller products in order to provide customers with ease of use. For semiconductor packaging process, the manufacturing method trends to high quantity, high quality and low cycle time. According to these requirements for packaging process, the mini ball grid array (mini BGA) has been developed. The manufacturing process of a mini BGA includes disposing chips on a substrate in array. The chips are electrically coupled to the substrate by wire bonding. The substrate with chips is transferred to a mold. Then, the chips are encapsulated by a molding compound. The substrate with chips is then split into many mini BGA packages.

FIG. 1 illustrates the cross section view for the encapsulating step of a conventional mini BGA packaging process. Referring to FIG. 1, a semi-finished product 100 is provided. The semi-finished product includes a substrate 110, a plurality of chips 120, and a plurality of wires 130. The substrate 110 has a surface 112, which a plurality of die pads 114 and a plurality of nodes 116 formed thereon. Each of the die pads 114 is surrounded by the nodes 116 respectively. Each of the chips 120 has an active surface 122 and a corresponding back surface 124. The chip 120 further has a plurality of bonding pads 126 located on the peripheral region of the active surface 122. The back surface of the chip 120 is attached to the die pad 114 of the substrate 110. The bonding pads 126 of the chips 120 are electrically coupled to the nodes 116 of the substrate 110 by the wires 130. Then, a base 140 is provided. The semi-finished product 100 is transferred to the base 140. A packaging mold 150 which has a cavity 152, at least one gate and an air vent is provided. The gate 154 is located at one side of the cavity 152, and the air vent is located at the other side, respectively. An encapsulating process is performed. A molding compound (not shown) is injected into the cavity 152 through the gate 154 and flowed to the air vent 156. When the flow of the molding compound arrives at the air vent 156, the injection stops and the encapsulating process is accomplished.

Generally speaking, in order to prevent the generation of a void in the encapsulating process, a plurality of air vents are designed in a mold to improve the air exhaust. However, in the case of a molding compound of small grain, the molding compound will jam the air vent 156 before it fills the cavity 152. Thus, the flow of molding compound will become non-uniform, and probably result in a void.

### SUMMARY OF THE INVENTION

Accordingly, one aspect of the present invention is to provide a mold for an integrated circuit package which prevents the jam of the air vent.

Another aspect of the present invention is to provide a mold for an integrated circuit package which improves the air exhaust.

Still, another aspect of the present invention is to provide a mold for an integrated circuit package which improves the uniformity of the flow of the molding compound.

According to the different aspects of the invention described above, a mold for an integrated circuit package comprises a main body, a protrusion, a first baffle block, and a second baffle block. The protrusion surrounds the edges of the main body. The protrusion is divided into four portions, that is, a first sidewall, a second sidewall, a third sidewall and a fourth sidewall. A gate is formed on the top surface of the first sidewall. An air vent is formed on the top surface of the third sidewall. The first sidewall and the third sidewall are respectively located on the opposite sides of the protrusion. The second sidewall is approximately perpendicularly connected to the first sidewall and the third sidewall at the two ends thereof. The fourth sidewall is approximately perpendicularly connected to the first sidewall and the third sidewall at the two ends thereof. The fourth sidewall and the second sidewall are respectively located on the other opposite sides of the protrusion. The first baffle block is located among the protrusion and near the first sidewall. The extension direction of the first baffle block is substantially parallel to the first sidewall. The second baffle block is located among the protrusion and near the third sidewall. The extension direction of the second baffle block is substantially parallel to the third sidewall. The two ends of the second baffle block are connected to the second sidewall and the fourth sidewall respectively. The distance between the second baffle block and the third sidewall is much smaller than that between the second baffle block and the first sidewall.

According to the different aspects of the invention described above, a mold for an integrated circuit package comprises a main cavity, a front cavity, a rear cavity, a plurality of gates, and a plurality of air vents. The front cavity is located between the main cavity and the gates. The rear cavity is located between the main cavity and the air vents. The front cavity is interconnected with the main cavity and the gates so that they share a common inner space. The rear cavity is interconnected with the main cavity and the air vents so that they share a common inner space. The extension direction of the rear cavity is parallel to the arrangement direction of the air vents. The extension direction of the front cavity is parallel to the arrangement direction of the gates. The width of the rear cavity is smaller than that of the main cavity.

Owing to the rear cavity, the appearance of short shot and void will be happened in the rear cavity. Therefore, the defect will not arise in the final product so that the yield is improved. Besides, because of the second baffle block, the flow of the molding compound is baffled so that the filling of the main cavity is improved. When the molding compound flows through the second baffle block to the rear cavity, the temperature of the molding compound rises owing to the friction between the molding compound and the second baffle block. Thus, the molding compound is hardened rapidly so that the molding compound is solidified in the rear cavity. The jam of the air vent is prevented.

Both the foregoing general description and the following detailed description are exemplary and explanatory only and are not restrictive of the invention, as claimed.

### BRIEF DESCRIPTION OF THE DRAWINGS

FIG. 1 is a cross section view illustrating the encapsulating step of a conventional mini BGA packaging process.

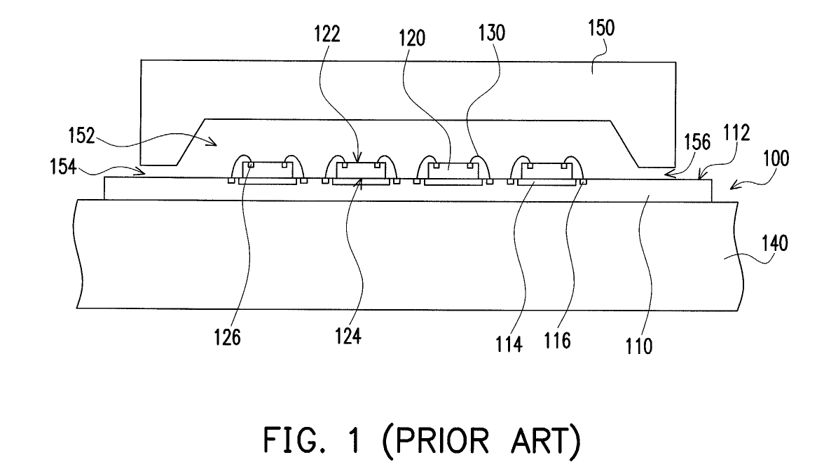

FIG. 2 is a cross section view illustrating the encapsulating step according to one preferable embodiment of the present invention.

FIG. 3 is a bottom view illustrating the mold for an integrated circuit package corresponding to FIG. 2.

FIG. 4 is a cross section view illustrating a semi-finished package according to one embodiment of the present invention.

### DESCRIPTION OF THE PREFERRED EMBODIMENTS

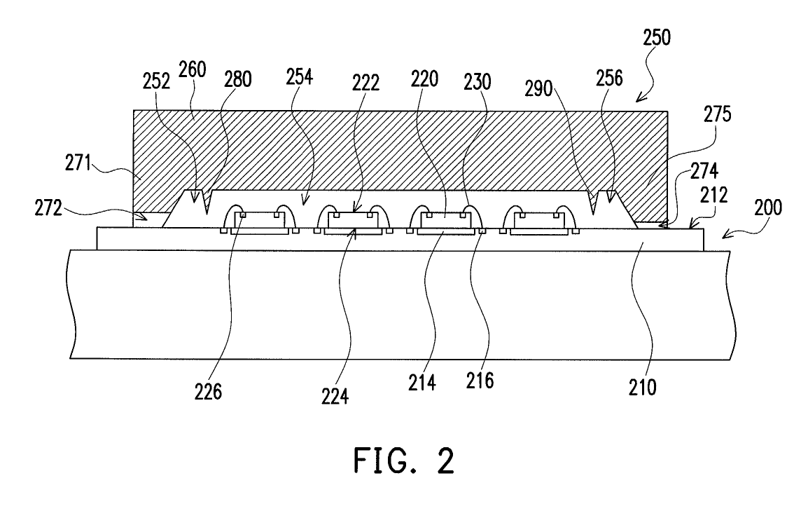

Referring to FIG. 2, a cross section view schematically illustrates an encapsulating step for a mini BGA package according to one preferred embodiment of the present invention. First, a semi-finished package 200 is provided. The semi-finished package 200 includes a substrate 210, a plurality of chips 220, and a plurality of wires 230. The substrate 210 has a surface 212, on which a plurality of die pads 214 and a plurality of nodes 216 are formed. Each of the die pads 214 is surrounded by the nodes 216 respectively. Each of the chips 220 has an active surface 222 and a corresponding back surface 224. The chip 220 further has a plurality of bonding pads 226 located on the peripheral region of the active surface 222. The back surface 224 of the chip 220 is attached to the die pad 214 of the substrate 210. The bonding pads 226 of the chips 220 are electrically coupled to the nodes 216 of the substrate 210 by the wires 230. However, the chips can be electrically coupled to the substrate by controlled collapse chip connection (flip chip). Because flip chip is a conventional technology for a person skilled in the art, the details will not described here.

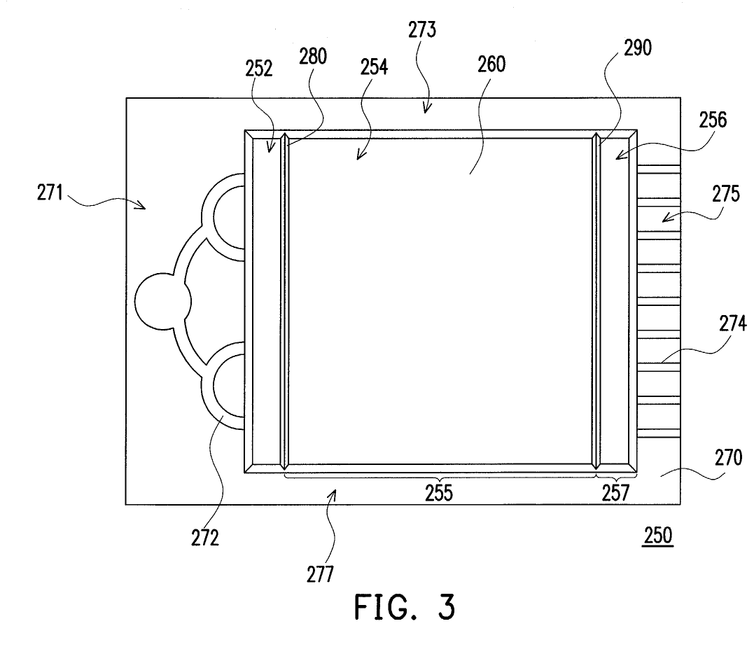

Then, a base 240 is provided. The semi-finished package 200 is transferred on the base 240. Referring to FIG. 2 and FIG. 3, FIG. 3 schematically illustrates a bottom view of a mold for an integrated circuit package corresponding to FIG. 2. A mold 250 for an integrated circuit package is provided. The mold 250 for an integrated circuit package comprises a main body 260, a protrusion 270, a first baffle block 280, and a second baffle block 290. The main body 260, the protrusion 270, the first baffle block 280 and the second baffle block 290 are integrally formed. The protrusion 270 is formed on the main body 260, and surrounds the edges of the main body 260. The protrusion 270 is divided into four portions, that is, a first sidewall 271, a second sidewall 273, a third sidewall 275 and a fourth sidewall 277. A gate 272 is formed on the top surface of the first sidewall 271. An air vent is formed on the top surface of the third sidewall 275. The first sidewall 271 and the third sidewall 275 are respectively located on the opposite sides of the protrusion 270. The second sidewall 273 is approximately perpendicularly connected to the first sidewall 271 and the third sidewall 275 at the two ends thereof. The fourth sidewall 277 is approximately perpendicularly connected to the first sidewall 271 and the third sidewall 275 at the two ends thereof. The fourth sidewall 277 and the second sidewall 273 are respectively located on the other opposite sides of the protrusion 270. The first baffle block 280 is located among the protrusion 270 and near the first sidewall 271. The extension direction of the first baffle block 280 is substantially parallel to the first sidewall 271. The second baffle block 290 is located among the protrusion 270 and near the third sidewall 275. The extension direction of the second baffle block 290 is substantially parallel to the third sidewall 275. The two ends of the second baffle block 290 are connected to the second sidewall 273 and the fourth sidewall 277 respectively. The distance between the second baffle block 290 and the third sidewall 275 is much smaller than that between the second baffle block 290 and the first sidewall 271. Besides, the length of the second baffle block 290 is substantially the same as the length of third sidewall 275. The cross section of the second baffle block is formed as a triangle.

As the structure of the mold 250 described above, a main cavity 254 is formed between the first baffle block 280, the second sidewall 273, the second baffle block 290 and the fourth sidewall 277. A rear cavity 256 is formed between the second baffle block 290, the second sidewall 273, the third sidewall 275 and the fourth sidewall 277. Further, a front cavity 252 is formed between the first sidewall 271, the second sidewall 273, the first baffle block 280 and the fourth sidewall 277. Therefore, the front cavity 252 is located between the main cavity 254 and the gate 272. The rear cavity 256 is located between the main cavity 254 and the air vents 274. The front cavity 252 is interconnected with the main cavity 254 and the gates 272 so that they share a common inner space. The rear cavity 256 is interconnected with the main cavity 254 and the air vents 274 so that they share a common inner space. The extension direction of the rear cavity 256 is parallel to the arrangement direction of the air vents 274. The width 257 of the rear cavity 256 is much smaller than the width 255 of the main cavity 254 so that the space of the main cavity 254 is much lager than the space of the rear cavity 256.

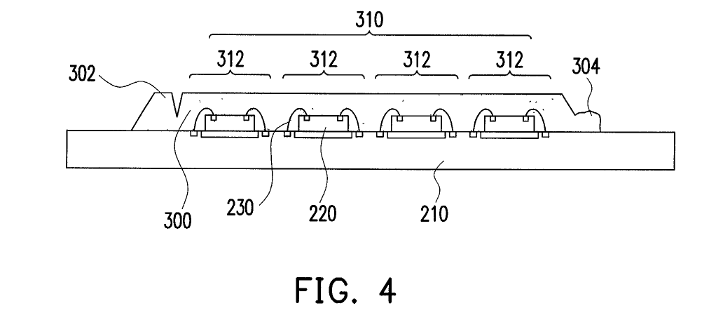

Referring to FIG. 2, FIG. 3 and FIG. 4, FIG. 4 is a cross section view of a semi-finished package according to one preferred embodiment of the present invention. As an encapsulating step proceeds, a molding compound 300 is injected into the front cavity 252 through the gates 272. Because the first baffle block 280 resists a portion of the flow of the molding compound and sustains a portion of the injection pressure, the flow becomes more uniform when it is injected into the main cavity 254. Then, the main cavity 254 is filled with the molding compound 300 gradually so that the chip 220, the wires 230, and the substrate 210 are encapsulated. A package structure 310 is formed. The molding compound 300 flows to the rear cavity 256 continuously, until the rear cavity 256 is filled with the molding compound 300. Then, the encapsulating step is accomplished. When the molding compound 300 is setting, a first package block 302 is formed in the front cavity 252 and a second package block 304 is formed in the rear cavity 256. The first package block 302 and the second package block 304 are connected to two sides of the package structure 310 respectively. Next, a separating step is processed. The package structure 310 is separated into a plurality of packages 312, and the first package block 302 and the second package block 304 are trimmed.

As the encapsulation process descried above, owing to the rear cavity 256, the appearance of short shot and void will happen in the rear cavity 256. Therefore, the defect will not arise in the final product so that the yield is improved. In addition, owing to the second baffle block 290 which resists a portion of the flow of the molding compound 300, the filling of the main cavity 254 is improved. Moreover, the second baffle block 290 provides a narrow gap in the mold. When the molding compound 300 flows through the gap, it sustains a friction force and a pressure so that the molding compound 300 is heated. Therefore, the hardening of the molding compound 300 is accelerated. That is, the molding compound 300 sets rapidly when it flows into the rear cavity 256. Therefore, the jam of the air vents 274 is prevented.

To sum up, the present invention has advantages as follow:

1. Owing to the rear cavity of the mold, the appearance of short shot and void will happen in the rear cavity. Therefore, the defect will not arise in the final product so that the yield is improved.

2. Owing to the second baffle block, the filling of the main cavity is improved. When the molding compound flows through the gap between the second baffle block and the substrate, it sustains a friction force and a pressure so that the molding compound is heated. Therefore, the hardening of the molding compound is accelerated. That is, the molding compound sets rapidly when it flows into the rear cavity. Therefore, the jam of the air vents 274 is prevented.

Other embodiments of the invention will appear to those skilled in the art from consideration of the specification and practice of the invention disclosed herein. It is intended that the specification and examples are to be considered as exemplary only, with a true scope and spirit of the invention being indicated by the following claims.

What is claimed is:

1. A mold for an integrated circuit package, comprising:
a main body;
a protrusion located on the main body, wherein the protrusion is formed in the shape of a rectangular ring, the protrusion including:
a first sidewall located on the main body, wherein the first sidewall has a gate formed on the top surface of the first sidewall;
a second sidewall located on the main body;
a third sidewall located on the main body, wherein the third sidewall has an air vent formed on the top surface of the third sidewall, wherein the first sidewall and the third sidewall are respectively located on the opposite sides of the protrusion, and wherein the second sidewall is approximately perpendicularly connected to the first sidewall and the third sidewall at the two ends thereof;
a fourth sidewall located on the main body, wherein the fourth sidewall is approximately perpendicularly connected to the first sidewall and the third sidewall at the two ends thereof, and wherein the fourth sidewall and the second sidewall are respectively located on another opposite sides of the protrusion;
a first baffle block located among the protrusion and near the first sidewall, wherein the extension direction of the first baffle block is substantially parallel to the first sidewall, and wherein the first baffle block is approximately perpendicularly connected to the second sidewall and the fourth sidewall at the two ends thereof; and
a second baffle block located among the protrusion and near the third sidewall, wherein the extension direction of the second baffle block is substantially parallel to the third sidewall, and wherein the distance between the second baffle block and the third sidewall is much smaller than that between the second baffle block and the first sidewall.

2. The mold for an integrated circuit package according to claim 1, wherein the main body, the protrusion, the first baffle block and the second baffle block are integrally formed.

3. The mold for an integrated circuit package according to claim 1, wherein the cross section of the first baffle block is formed in the shape of a triangle.

4. The mold for an integrated circuit package according to claim 1, wherein the cross section of the second baffle block is formed in the shape of a triangle.

5. The mold for an integrated circuit package according to claim 1, wherein the second baffle block is connected to the second sidewall and the fourth sidewall at the two ends thereof.

6. A mold for an integrated circuit package, comprising:
a main body;
a protrusion located on the main body, wherein the protrusion is formed in the shape of a ring, wherein the protrusion includes a plurality of sidewalls and the protrusion has a gate and an air vent, and wherein the air vent is located on one of the sidewalls so that a molding compound can be injected into the space among the ring-like protrusion through the gate; and
a baffle block located among the ringlike protrusion and near the sidewall on which the air vent is formed, wherein the extension direction of the baffle block is substantially parallel to the sidewall with the air vent, and wherein the distance between the baffle block and the sidewall with the air vent is much smaller than that between the baffle block and the sidewall opposite to the sidewall with the air vent.

7. The mold for an integrated circuit package according to claim 6, wherein the main body, the protrusion, the baffle block are integrally formed.

8. The mold for an integrated circuit package according to claim 6, wherein the length of the baffle block is substantially equal to the length of the sidewall with the air vent.

9. A mold for an integrated circuit package including a main cavity, a front cavity, a rear cavity, a plurality of gates and a plurality of air vents, wherein the gates and the air vents are located on two opposite sides of the mold respectively, wherein the front cavity is located between the main cavity and the gates and the rear cavity is located between the main cavity and the air vents, wherein the front cavity is interconnected with the gates and the main cavity so that they share a common space, and the rear cavity is interconnected with the main cavity and the air vents so that they share a common inner space, wherein the extension direction of the rear cavity is parallel to the arrangement direction of the air vents, and the extension direction of the front cavity is parallel to the arrangement direction of the gates, and wherein the space of the main cavity is much lager than the space of the rear cavity.

10. A mold for an integrated circuit package including a main cavity, a front cavity, a rear cavity, a plurality of gates and a plurality of air vents, wherein the gates and the air vents are located on two opposite sides of the mold respectively, wherein the front cavity is located between the main cavity and the gates and the rear cavity is located between the main cavity and the air vents, wherein the front cavity is interconnected with the gates and the main cavity so that they share a common space, and the rear cavity is interconnected with the main cavity and the air vents so that they share a common inner space, and wherein the space of the main cavity is much lager than the space of the rear cavity.
